(19) United States
(12) Patent Application Publication
(10) Pub. No.: US 2011/0126852 A1
(43) Pub. Date: Jun. 2, 2011

(54) ELECTROSTATIC CHUCK WITH AN ANGLED SIDEWALL

(75) Inventors: Rajinder Dhindsa, San Jose, CA (US); Pratik Mankidy, Fremont, CA (US); Chris Kimball, San Jose, CA (US)

(73) Assignee: Lam Research Corporation, Fremont, CA (US)

(21) Appl. No.: 12/956,727

(22) Filed: Nov. 30, 2010

Related U.S. Application Data
(60) Provisional application No. 61/265,200, filed on Nov. 30, 2009.

(51) Int. Cl. B08B 7/00; H01L 21/3065

(52) U.S. Cl. 134/1.1; 156/345.51

(57) ABSTRACT

A substrate support for a plasma processing chamber has an angled sidewall at an upper periphery thereof. The substrate is surrounded by an edge ring which underlies a substrate supported on an upper substrate support surface of the substrate support during plasma processing. The angled sidewall is the only surface of the substrate support exposed and subject to byproduct deposition during plasma processing. The angled sidewall enhances sputtering rate of the byproduct deposition during an in situ chamber clean process wherein a cleaning gas supplied to the chamber is energized into a plasma state for cleaning the byproduct deposition.

This application claims priority under 35 U.S.C. §119 to U.S. Provisional Application No. 61/265,200 entitled AN ELECTROSTATIC CHUCK WITH AN ANGLED SIDEWALL, filed Nov. 30, 2009, the entire content of which is hereby incorporated by reference.

### BACKGROUND

With each successive semiconductor technology generation, wafer diameters tend to increase and transistor sizes decrease, resulting in the need for an ever higher degree of accuracy and repeatability in wafer processing. Semiconductor substrate materials, such as silicon wafers, are processed by techniques which include the use of vacuum chambers. These techniques include non-plasma applications such as electron beam evaporation, as well as plasma applications, such as sputter deposition, plasma-enhanced chemical vapor deposition (PECVD), resist strip, and plasma etch.

Exemplary plasma processing chambers are described in commonly owned U.S. Pat. Nos. 4,340,462, 4,948,458, 5,200,232, 6,090,304 and 5,820,723, which are hereby incorporated by reference. A plasma processing chamber can comprise an upper electrode assembly and a lower electrode assembly. Details of exemplary upper electrode assemblies are disclosed in U.S. Pat. Nos. 6,333,272, 6,230,651, 6,013,155 and 5,824,605, which are hereby incorporated by reference. Directly below the upper electrode assembly, is the lower electrode assembly which can comprise an electrostatic chuck (ESC) on which the substrate being processed is supported. Exemplary ESCs are described in commonly owned U.S. Pat. Nos. 7,161,121, 6,669,783 and 6,483,690, which are incorporated by reference. The ESC can have micro channels on its upper surface in fluidic communication with a helium gas source. Helium gas can be used to cool the substrate during processing. A method of controlling a temperature of a substrate by a pressurized gas is disclosed in commonly-owned U.S. Pat. No. 6,140,612, which is hereby incorporated by reference. The lower electrode assembly can further comprise an edge ring fitted around the substrate. Exemplary edge rings are described in commonly owned U.S. Patent Application Publication No. 2009/0186487 and U.S. Pat. Nos. 5,805,408, 5,998,932, 6,013,984, 6,039,836 and 6,383,931, which are incorporated by reference.

In a typical plasma processing chamber, plasma density is lower near the edge of the substrate, which can lead to accumulation of a byproduct layer (such as polymer, poly-silicon, nitride, metal, etc.) on the top and bottom surfaces of the substrate edge and surfaces of chamber components nearby. Excessive byproduct accumulation can lead to many problems in plasma processing such as particle contamination, unreliable substrate clamping, cooling He gas leakage, reduced efficiency and reduced device yield. Therefore, it is highly desirable to remove the byproduct. The byproduct layer on the substrate edge can be removed by using a plasma bevel etcher. An exemplary plasma bevel etcher is described in commonly owned U.S. Patent Application Publication No. 2008/0227301, which is hereby incorporated by reference. The byproduct layer on chamber components is more difficult to remove, partially due to their complicated shapes. A typical plasma processing chamber can run a chamber clean process, in which a plasma is used to etch the byproduct layer from chamber components without presence of the substrate.

### SUMMARY

Described herein is a substrate support for supporting a substrate in a plasma processing chamber which comprises an upper substrate support surface dimensioned to support the substrate during plasma processing such that the substrate extends outward of an outer periphery of the upper substrate support surface, and an angled sidewall extending outward and downward from the outer periphery of the upper substrate support surface, the angled sidewall configured to have an outer periphery substantially coplanar with an upper surface of an edge ring surrounding the substrate support, the upper surface of the edge ring at least partially under a peripheral portion of the substrate, wherein the angled sidewall accumulates byproduct deposition during plasma processing.

### BRIEF DESCRIPTION OF FIGURES

FIG. 1 shows an cross sectional schematic of a prior art lower electrode assembly.

FIG. 2 shows an enlarged view of the portion A in FIG. 1.

FIG. 3 shows an enlarged view of the portion A in FIG. 1 during a chamber clean process.

FIG. 4A is a schematic graph of sputtering efficiency of a plasma exposed surface as a function of ions incident angle.

FIG. 4B is a schematic graph of relative ion flux received by a plasma exposed surface as a function of ions incident angle.

FIG. 5 shows a cross sectional schematic of a lower electrode assembly comprising an electrostatic chuck with an angled sidewall, in the proximity of an overhanging substrate.

FIG. 6 shows a lower electrode assembly comprising an electrostatic chuck with an angled sidewall during a chamber clean process.

### DETAILED DESCRIPTION

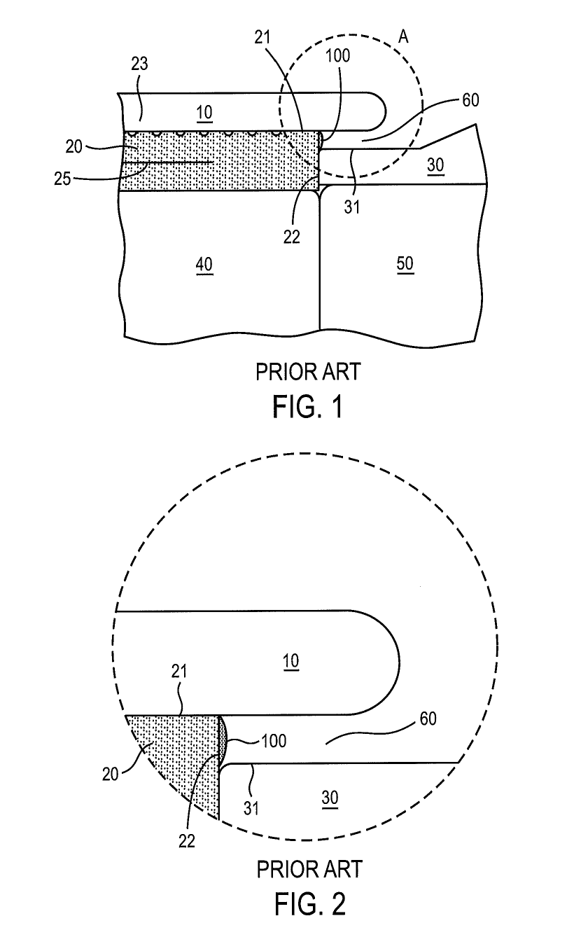

FIG. 1 shows a schematic cross section of a prior art lower electrode assembly. FIG. 2 shows an enlarged view of detail A in FIG. 1. A substrate 10 is supported on a support surface 21 of an ESC 20. For purposes of introducing a heat transfer gas such as helium beneath the substrate, the ESC 20 may include a pattern of grooves, mesas, openings or recessed regions 23 in fluidic communication with a helium gas source (not shown). Details of ESC features are disclosed in commonly owned U.S. Pat. No. 7,501,605. An electrode 25 is embedded in the ESC 20 for electrostatically clamping the substrate 10 during processing. The ESC 20 has a vertical sidewall 22 and is sized so that, during processing, a peripheral portion of the substrate 10 overhangs the ESC 20 and overlies an upper surface 31 of an edge ring 30 surrounding the ESC 20, with a gap 60 between the upper surface 31 and the substrate 10. The ESC 20 is supported on a support member 40 and the edge ring 30 is supported on a support member 50.

During processing, a byproduct deposit 100 can accumulate on a portion of the vertical sidewall 22 exposed in the gap 60. Excessive byproduct on the vertical sidewall 22 can cause He leakage from the pattern of grooves, mesas, openings or recessed regions 23 and affect electrostatic clamping of the substrate 10. The byproduct deposit 100 can be minimized by having a large substrate overhang and precise control on the size of the gap 60. However, in current semiconductor fabrication practice, a width of the substrate overhang can be as little as 1 mm in order to maximize device yield from the substrate. A substrate overhang with a small width such as 1 mm can lead to byproduct accumulation on the vertical sidewall 22 at a faster rate than desired.

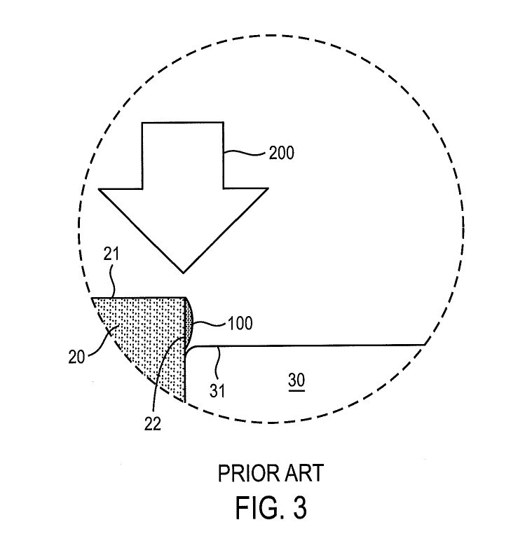

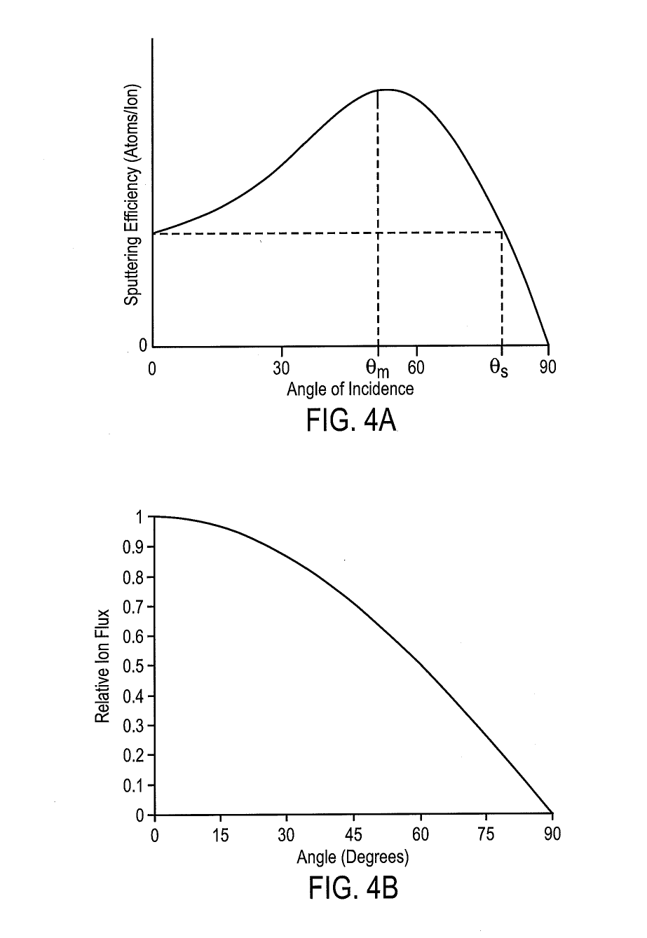

As shown in FIG. 3, the byproduct deposit 100 can be removed by running a chamber clean process, in which plasma is generated in the plasma processing chamber without the substrate 10 on the ESC 20. Ions 200 in the plasma are accelerated vertically by an electric field on the ESC 20 and sputter and/or chemically etch the byproduct deposit 100. FIG. 4A is a schematic graph showing sputtering efficiency (measured by the average number of atoms removed by an incoming ion) as a function of ion incident angles. The angle of incidence or the incidence angle is the angle between a ray of ions incident on a surface and a line perpendicular to the surface at the point of incidence. FIG. 4B is a schematic graph which represents relative ion flux received by the byproduct deposit 100 as a function of ion incident angles. Higher ion flux results in higher chemical etching efficiency. Because the vertical sidewall 22 is substantially parallel to the incident direction of the ions 200, the angle of incidence is nearly 90°, at which both the sputtering efficiency and the chemical etching efficiency are very low. Failure to remove all of the byproduct deposit 100 can lead to arcing, damage to the ESC, frequent chamber cleaning, and reduced efficiency of the plasma processing chamber, in addition to non-uniform substrate temperature caused by He leakage and unreliable clamping.

Described herein is an ESC with an angled sidewall, configured to enhance the sputter efficiency during the chamber clean process.

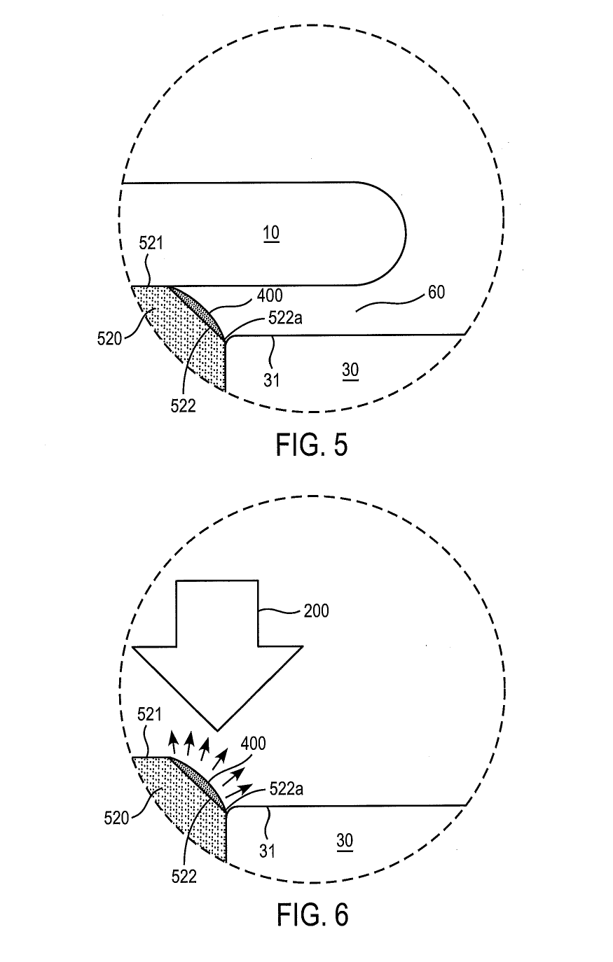

An embodiment is shown in FIG. 5. An ESC 520 comprises a support surface 521 and an angled surface 522 extending outward and downward from an outer periphery of the support surface 521. The angled surface 522 is sufficiently wide so that only the angled surface 522 is exposed in the gap 60 between the edge ring 30 and the substrate 10, i.e. the upper surface 31 of the edge ring 30 is substantially co-planar with an outer periphery 522a of the angled surface 522. Preferably, a peripheral portion of the substrate 10 overlying the upper surface 31 has a width from 1 to 3 mm. The ESC 520 can comprise other conventional features such as a pattern of grooves, mesas, openings or recessed regions on its upper surface for distribution of He gas and an embedded electrode for electrostatically clamping the substrate 10 during processing.

Because the ESC 520 is configured such that only the angled surface 522 is exposed during plasma processing of a substrate, byproduct deposit 400 occurs only on the angled surface 522. In the chamber clean process as shown in FIG. 6, the angle of incidence of the ions 200 is approximately the acute angle between the angled surface 522 and the support surface 521, which is substantially smaller than the nearly 90° angle of incidence in the case of a vertical sidewall. The acute angle between the angled surface 522 and the support surface 521 is preferably from 35° to 75°, further preferably from 45° to 60°. The angled surface 522 preferably has a width from 0.005 to 0.04 inch, more preferably from 0.01 to 0.03 inch.

While the ESC with angled sidewall has been described in detail with reference to specific embodiments thereof, it will be apparent to those skilled in the art that various changes and modifications can be made, and equivalents employed, without departing from the scope of the appended claims. For example, the angled sidewall can be incorporated in other chamber components that suffer from byproduct deposition, such as other types of substrate support (e.g. vacuum chucks), edge rings, coupling rings and the like.

We claim:

1. A substrate support, for supporting a substrate in a plasma processing chamber configured for etching the substrate, the substrate support comprising:
an upper substrate support surface dimensioned to support the substrate during plasma processing such that the substrate extends outward of an outer periphery of the upper substrate support surface, and
an angled sidewall extending outward and downward from the outer periphery of the upper substrate support surface, the angled sidewall configured to have an outer periphery substantially coplanar with an upper surface of an edge ring surrounding the substrate support, the upper surface of the edge ring facing a lower surface of a peripheral portion the substrate,
wherein the angled sidewall accumulates byproduct deposition during plasma processing.

2. The substrate support of claim 1, wherein an acute angle between the angled sidewall and the upper substrate support surface is from 35° to 75°.

3. The substrate support of claim 1, wherein an acute angle between the angled sidewall and the upper substrate support surface is from 45° to 60°.

4. The substrate support of claim 1, wherein the angled sidewall has a width from 0.005 to 0.04 inch.

5. The substrate support of claim 1, wherein the angled sidewall has a width from 0.01 to 0.03 inch.

6. The substrate support of claim 1, further comprising:
an embedded electrode configured to electrostatically clamp the substrate;
at least one groove, mesa, opening or recessed region in the upper substrate support surface, the groove, mesa, opening or recessed region being in fluidic communication with a helium gas source, and configured to effect heat transfer between the upper substrate support surface and the substrate during plasma processing.

7. The substrate support of claim 1, wherein the substrate support is sized such that a width of the peripheral portion of the substrate overhanging the substrate support is 1 to 3 mm.

8. A lower electrode assembly in a plasma processing chamber, configured to support a substrate during plasma processing, the lower electrode assembly comprising the substrate support of claim 1 and an edge ring surrounding the substrate support, wherein:
a peripheral portion of the substrate overhangs the substrate support and overlies an upper surface of the edge ring;
the upper surface of the edge ring is substantially co-planar with the outer periphery of the angled sidewall of the substrate support.

9. A method of removing byproduct deposition on the angled sidewall of the substrate support of claim 1, the method comprising:
generating a plasma above the substrate support without a substrate thereon;
bombarding the byproduct deposition with the plasma.
